(19) United States
(12) Patent Application Publication
(10) Pub. No.: US 2019/0300361 A1
(43) Pub. Date: Oct. 3, 2019

(54) MEMS DEVICES AND PROCESSES

(71) Applicant: Cirrus Logic International Semiconductor Ltd., Edinburgh (GB)

(72) Inventor: Richard Ian LAMING, Edinburgh (GB)

(73) Assignee: Cirrus Logic International Semiconductor Ltd., Edinburgh (GB)

(21) Appl. No.: 15/938,524

(22) Filed: Mar. 28, 2018

(51) Int. Cl. B81B 3/00; H04R 19/04; H04R 19/00

(52) U.S. Cl. CPC B81B 3/0086; B81B 3/0021; H04R 19/04; H04R 19/005; H04R 2499/11; B81B 2203/04; B81B 2203/0127; B81B 2207/012; H04R 2201/003; B81B 2201/0257

(57) ABSTRACT

The application relates to a MEMS transducer comprising first and second conductive elements which defines a capacitor of the transducer, and a third conductive element. The third conductive element is configured to be at a potential substantially the same as that of the second conductive element, and is provided in a plane that overlies the plane of the second conductive element.

### TECHNICAL FIELD

This application relates to micro-electro-mechanical system (MEMS) devices and processes, and in particular to a MEMS device and process relating to a transducer, for example a capacitive microphone.

### BACKGROUND INFORMATION

MEMS devices are becoming increasingly popular. MEMS transducers, and especially MEMS capacitive microphones, are increasingly being used in portable electronic devices such as mobile telephone and portable computing devices.

Microphone devices formed using MEMS fabrication processes typically comprise one or more moveable membranes and a static backplate, with a respective electrode deposited on the membrane(s) and backplate, wherein one electrode is used for read-out/drive and the other is used for biasing. A substrate supports at least the membrane(s) and typically the backplate also. In the case of MEMS pressure sensors and microphones the read out is usually accomplished by measuring the capacitance between the membrane and backplate electrodes. In the case of transducers, the device is driven, i.e. biased, by a potential difference provided across the membrane and backplate electrodes.

FIG. 1A and FIG. 1B show a schematic diagram and a perspective view, respectively, of a known capacitive MEMS microphone device 100. The capacitive microphone device 100 comprises a membrane layer 101 which forms a flexible membrane which is free to move in response to pressure differences generated by sound waves. A first electrode 102 is mechanically coupled to the flexible membrane, and together they form a first capacitive plate of the capacitive microphone device. A second electrode 103 is mechanically coupled to a generally rigid structural layer or back-plate 104, which together form a second capacitive plate of the capacitive microphone device. In the example shown in FIG. 1a the second electrode 103 is embedded within the back-plate structure 104.

The capacitive microphone is formed on a substrate 105, for example a silicon wafer which may have upper and lower oxide layers 106, 107 formed thereon. A cavity 108 in the substrate and in any overlying layers (hereinafter referred to as a substrate cavity) is provided below the membrane, and may be formed using a “back-etch” through the substrate 105. The substrate cavity 108 connects to a first cavity 109 located directly below the membrane. These cavities 108 and 109 may collectively provide an acoustic volume thus allowing movement of the membrane in response to an acoustic stimulus. Interposed between the first and second electrodes 102 and 103 is a second cavity 110. A plurality of holes, hereinafter referred to as bleed holes 111, connect the first cavity 109 and the second cavity 110.

A plurality of acoustic holes 112 are arranged in the back-plate 104 so as to allow free movement of air molecules through the back plate, such that the second cavity 110 forms part of an acoustic volume with a space on the other side of the back-plate. The membrane 101 is thus supported between two volumes, one volume comprising cavities 109 and substrate cavity 108 and another volume comprising cavity 110 and any space above the back-plate. These volumes are sized such that the membrane can move in response to the sound waves entering via one of these volumes. Typically the volume through which incident sound waves reach the membrane is termed the “front volume” with the other volume, which may be substantially sealed, being referred to as a “back volume”.

In some applications the backplate may be arranged in the front volume, so that incident sound reaches the membrane via the acoustic holes 112 in the backplate 104. In such a case the substrate cavity 108 may be sized to provide at least a significant part of a suitable back-volume. In other applications, the microphone may be arranged so that sound may be received via the substrate cavity 108 in use, i.e. the substrate cavity forms part of an acoustic channel to the membrane and part of the front volume. In such applications the backplate 104 forms part of the back-volume which is typically enclosed by some other structure, such as a suitable package.

It should also be noted that whilst FIGS. 1A and 1B shows the backplate being supported on the opposite side of the membrane to the substrate, arrangements are known where the backplate is formed closest to the substrate with the membrane layer supported above it.

In use, in response to a sound wave corresponding to a pressure wave incident on the microphone, the membrane is deformed slightly from its equilibrium or quiescent position. The distance between the membrane electrode 102 and the backplate electrode 103 is correspondingly altered, giving rise to a change in capacitance between the two electrodes that is subsequently detected by electronic circuitry (not shown).

The membrane layer and thus the flexible membrane of a MEMS transducer generally comprises a thin layer of a dielectric material—such as a layer of crystalline or polycrystalline material. The membrane layer may, in practice, be formed by several layers of material which are deposited in successive steps. Thus, the flexible membrane 101 may, for example, be formed from silicon nitride Si₃N₄ or polysilicon. Crystalline and polycrystalline materials have high strength and low plastic deformation, both of which are highly desirable in the construction of a membrane. The membrane electrode 102 of a MEMS transducer is typically a thin layer of metal, e.g. aluminium, which is typically located in the centre of the flexible membrane 101, i.e. that part of the membrane which displaces the most. It will be appreciated by those skilled in the art that the membrane electrode may be formed by depositing a metal alloy such as aluminium-silicon for example. The membrane electrode may typically cover, for example, around 40% of area of the membrane, usually in the central region of the membrane.

Thus, known transducer membrane structures are composed of two layers of different material—typically a dielectric layer (e.g. SiN) and a conductive layer (e.g. AlSi).

It is known that some transducers demonstrate a degree of change—or drift—in sensitivity over time. Consequently, the capacitance (Ct) at a time t may be different to the initial operating capacitance Co. This can lead to a DC offset in the measurement signal from such a transducer, as the capacitance at the quiescent position is not the same. Furthermore, for a.c. audio signals, the change in capacitance leads to a variation in the signal charge for a given acoustic stimulus. A potential source of drift over time is time-dependent variation in the strength of the electric field between the electrodes of a sensing capacitor. Although the level or degree of sensitivity drift is typically very small, more recent applications of MEMS microphones (e.g. the use of MEMS microphones within a beamforming array of microphones) may require new levels of performance stability. Thus, there is a desire to further improve the stability of the sensitivity of MEMS transducers.

The present disclosure invention relates to MEMS transducers and processes which seek to alleviate the impact of sensitivity drift, by providing a MEMS transducer with a more stable sensitivity or performance over time.

### SUMMARY OF EMBODIMENTS

According to an example embodiment of an aspect, there is provided a MEMS transducer comprising first and second conductive elements, the second conductive element being provided in a plane which overlies a plane of the first conductive element, wherein a mutually overlapping region of the first and second conductive elements defines a capacitor of the transducer, the transducer further comprising a third conductive element, wherein the third conductive element is provided in a plane that overlies the plane of the second conductive element and wherein the third conductive element is configured to be at a potential substantially the same as the potential of the second conductive element. The third conductive element may provide an electric field which is stable over long periods of time, thereby alleviating the effects of sensitivity drift in the MEMS transducer.

According to an example embodiment of a further aspect, there is provided a MEMS transducer comprising first and second conductive elements of a capacitor, the MEMS transducer further comprising a field modifier provided in a fringing field region of the capacitor, the field modifier located to provide a stable electric field between the first conductive element and the field modifier. By providing a stable electric field with the first conductive element, the field modifier may reduce sensitivity drift in the MEMS transducer.

According to an example embodiment of a further aspect, there is provided a MEMS transducer comprising: a flexible membrane; a rigid backplate; a membrane electrode formed on an upper surface of the membrane; a backplate electrode, formed on or within the backplate; and a third conductive element provided at a potential the same as the potential of the backplate electrode. According to an example embodiment of a further aspect, there is provided a MEMS capacitive transducer comprising first and second parallel plates, the transducer further comprising a third plate, wherein the third plate is provided in a plane that overlies the plane of the second plate and wherein the third plate is configured to be at a potential the same as the potential of the second plate. Both example embodiments provide a MEMS transducer that may be less prone to sensitivity drift than existing MEMS transducers.

The third conductive element may be electrically connected to the second conductive element, thereby simply providing a system that ensures the second and third conductive elements are operated at substantially the same potential.

The third conductive element may at least partially, and optionally fully, overlie the second conductive element when viewed in a direction normal to the third conductive element. In this way, the third conductive element may be optimally positioned to provide a stable electric field.

A bias voltage may be applied to the third conductive element, wherein the bias voltage is substantially equal to a bias voltage applied to the second conductive element. Alternatively, the second conductive element and the third conductive element may be coupled to ground potential. Again, these configuration options ensure that the second and third conductive elements are maintained at substantially the same potential.

Associated methods of fabricating a MEMS transducer are provided for each of the above aspects of embodiments and examples described herein.

### DESCRIPTION OF FIGURES

For a better understanding of the present invention and to show how the same may be carried into effect, reference will now be made, by way of example, to the accompanying drawings in which:

FIGS. 1A and 1B illustrate known capacitive MEMS transducers in section and perspective views;

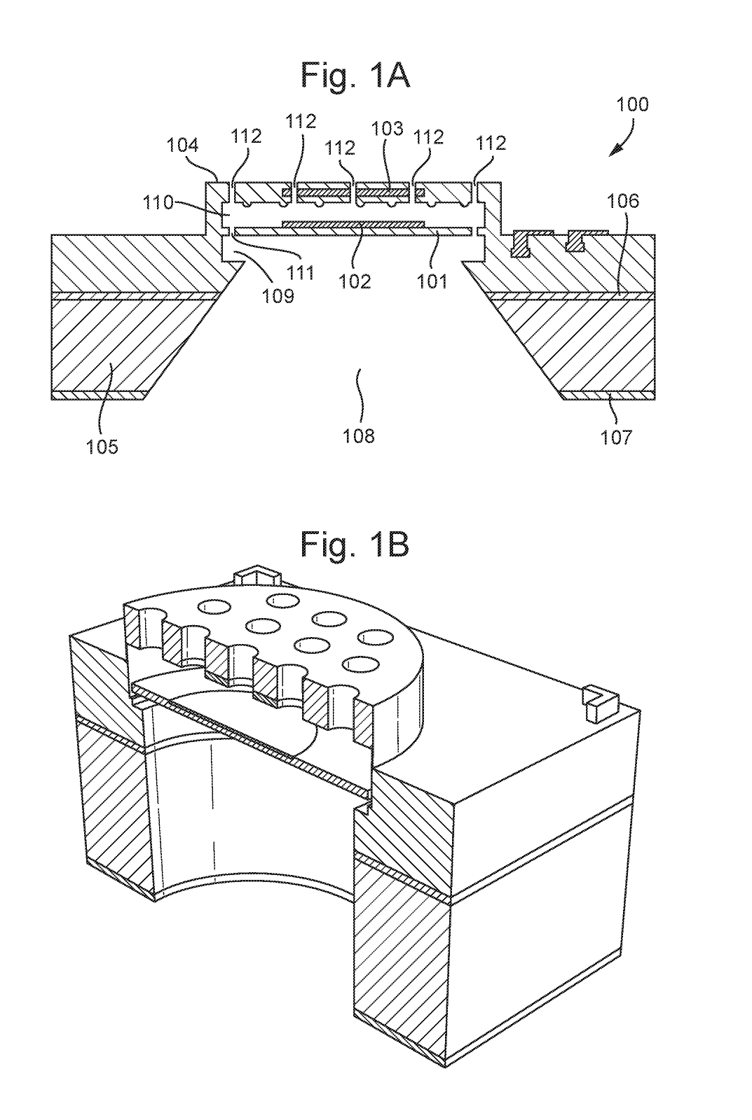

FIG. 2 illustrates electric field lines between first and second electrodes of a parallel plate capacitor;

FIG. 3A illustrates an initial electrical field between an electrode on a moveable membrane and an electrode on a support structure;

FIG. 3B illustrates the arrangement of FIG. 3A after a period of time has elapsed;

FIG. 4 illustrates a system comprising first, second and third conductive elements, in accordance with an example;

FIGS. 5A to 5E illustrate systems according to further examples of the present embodiments;

FIG. 6 illustrates an example comprising a conductive path between second and third conductive elements;

FIG. 7 illustrates an example comprising a second conductive element that is a hexagonal lattice.

It will be appreciated that the drawings may not be to scale and are for the purpose of illustration only. Consistent reference signs are used throughout the figures for components serving the same or similar purposes.

Examples described herein relate to MEMS capacitive transducers comprising a plurality of conductive elements. In the context of the examples described herein it is useful to consider the relative vertical spacing and/or horizontal (or lateral) locations of the conductive elements. Thus, the first conductive element is provided in a first substantially horizontal plane and the second conductive element is provided in a second substantially horizontal plane that is vertically spaced from the first horizontal plane. The first and second conductive elements are arranged to at least partially overlap in the horizontal plane. Thus, the mutually overlapping regions of the first and second conductive elements define first and second electrodes of a capacitor. As will be appreciated, the conductive elements referred to herein are substantially planar structures, having lengths and breadths that are significantly larger than the thicknesses (in the vertical direction) of the elements. The “plane” in which a conductive element lies should be understood as the plane containing the length and breadth of the respective conductive element.

According to one or more examples the second conductive element is vertically spaced from the first conductive element in a separation direction S and that the first and second conductive elements are arranged so as to be mutually overlapping. Thus the second conductive element 20 at least partially overlaps the first conductive element 10 when viewed in a direction normal/vertical to one of the first or second conductive elements.

Example embodiments of MEMS transducers described herein also comprise a third conductive element 30. The third conductive element 30 is provided in close proximity to the capacitor that is formed between the first and second conductive elements 10 and 20 respectively. The third conductive element 30 can be considered to be a ‘field modifier’ for modifying an electric field arising between the first and second conductive elements 10, 20. In particular, the third conductive element 30 may be provided in a plane that is spaced from the plane of the second conductive element 20 in the separation direction, i.e. vertically. Furthermore, the third conductive element 30 may be configured in use to be at a potential that is substantially the same as that of the second conductive element 20, in particular wherein the operating potential of the third conductive element 30 is the same as that of the second conductive element.

In use, in a MEMS capacitor with first and second electrodes, or plates, 10, 20, one of the first and second electrodes, or plates, 10, 20 of the capacitor is fixed, or rigid, whilst the other is arranged to be flexible such that it is displaced out of an equilibrium position in the substantially horizontal plane in response to e.g. an incident acoustic pressure wave across the electrodes, or plates, 10, 20. The change in distance between the electrode plates 10, 20 is measurable. Thus, example MEMS transducers rely on a capacitive sensing mechanism such that when the distance between the first and second electrodes 10, 20 is altered in response to an acoustic pressure differential between the electrodes 10, 20, a detectable change in capacitance between the two electrodes occurs. According to one arrangement, a fixed electrode (which is typically supported by a rigid support structure of the transducer, such as a backplate) is positively biased (e.g. at 12V) whilst a movable electrode that is supported by a flexible membrane of the transducer is negatively biased (for example, at 0 V). According to an alternative arrangement, said fixed electrode may be operatively negatively biased while said moveable or flexible electrode is operatively positively biased.

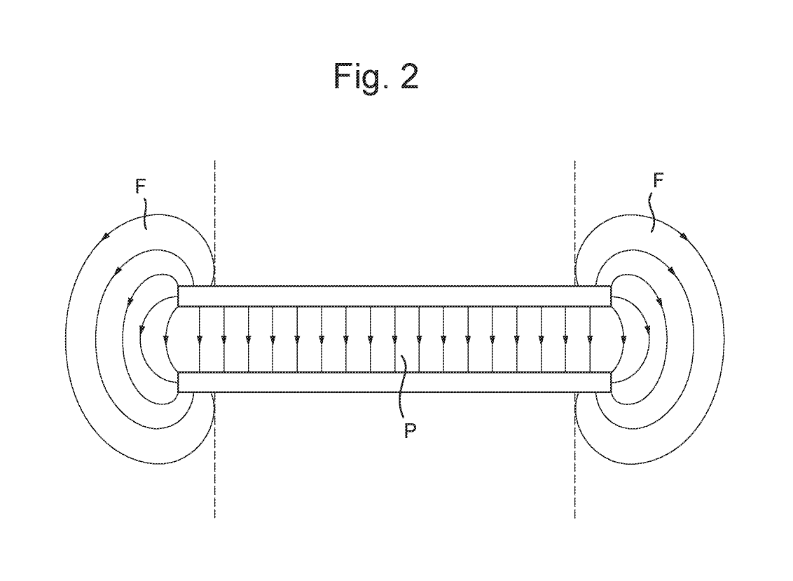

FIG. 2 illustrates the electric field arising between the first and second electrodes of a parallel plate capacitor. As one skilled in the art will appreciate, and as illustrated in FIG. 2, a parallel plate capacitor which is charged/biased gives rise to an electrostatic field component P extending from one plate to the other in a direction perpendicular to the plates. In addition, the edge of the plates effectively define a charge distribution boundary of the capacitor from which the electric field will extend or bow laterally. This region may be considered to be a fringing field region F of the capacitor.

Where one of the two electrodes is supported by a rigid support structure (such as a backplate), typically the remainder of the backplate is formed from an insulating material. As such, when the capacitor is initially created, the shape of the electrical field generated is not substantially altered by the support structure. However, in use, it is possible for moisture to accumulate on exposed surfaces of the support structure, for example, through the condensation of atmospheric moisture. A result of this moisture accumulation is that the exposed surfaces can exhibit surface conduction.

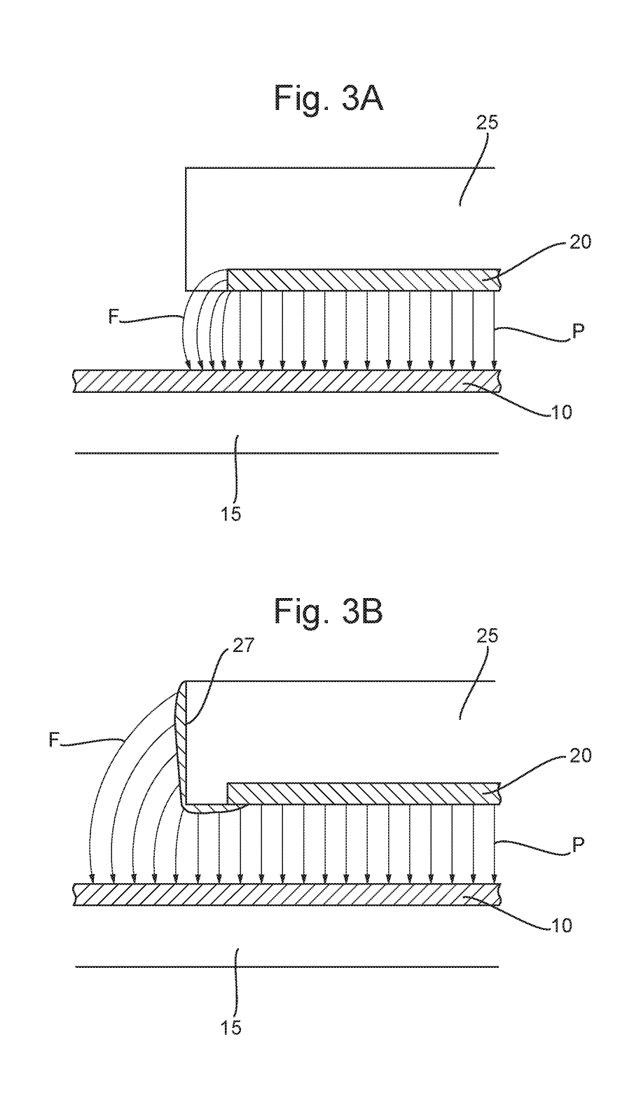

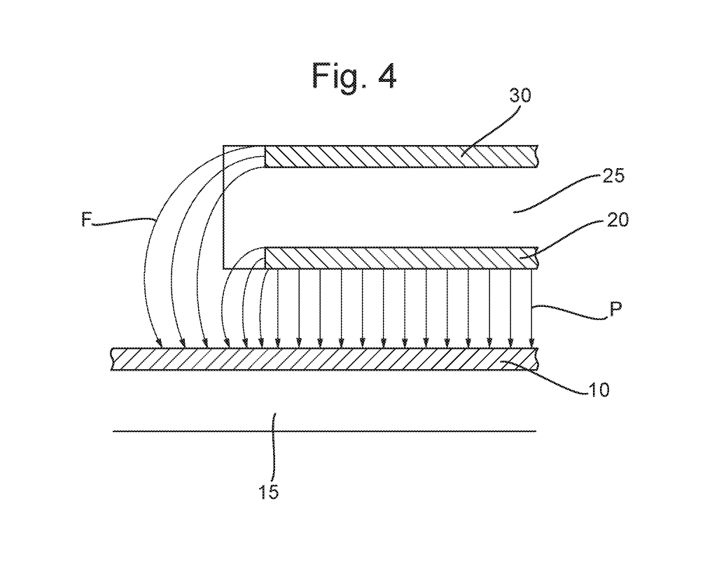

Increasing surface conductivity of the support structure can result in alterations in the shape of the fringing fields F. Essentially, a large area of the support structure surface can gradually be caused to drift to the same potential as that of the electrode supported by the support structure, resulting in the large area acting as the electrode and distorting the results provided by a capacitive sensor. This is shown in FIGS. 3A and 3B.

FIG. 3A shows the electrical field between an electrode 10 on a moveable membrane 15 and an electrode 20 on support structure 25 at initialisation (prior to the accumulation of moisture on the support structure 25). As can be seen from FIG. 3A, the field is largely confined to the region between the two electrodes 10, 20, and is largely perpendicular to the plane of the electrodes 10, 20. A small fringing field F region exists at the edge of the perpendicular field P. The shape of the field shown in FIG. 3A, can be contrasted with that shown in FIG. 3B.

FIG. 3B, shows the same configuration following the accumulation of moisture 27 on the surface of the support structure 25 (over a period of operation). The accumulation of moisture 27 over time leads to surface conductivity on the surface of the support structure, resulting in a gradual alteration in the shape of the fringing fields F, as shown in FIG. 3B (after a long period of accumulation), and thereby gradually altering the capacitance between the electrodes 10, 20 and causing sensitivity drift.

In examples described herein, a third conductive element is used to mitigate the effects of moisture accumulation on the support structure. The third conductive element is provided in a plane that overlies the plane in which the second conductive element is provided, such that the second conductive element lies at least partially between the first conductive element and the third conductive element. Typically, although not essentially, where the second conductive element is attached to or incorporated within the support structure, the third conductive element may also be attached to or incorporated within the support structure. Alternatively, the third conductive element may be provided on or in a further support element.

The third conductive element is configured to operate at a potential which is substantially the same as that of the second conductive element, optionally wherein the potential of the third conductive element is the same as that of the second conductive element. The presence of the third conductive element causes the electrical field shape which was previously established over time due to the increase in surface conductivity of the support structure (as shown in FIGS. 3A and 3B, which show an initial state and a later stage state respectively) to be established immediately upon the activation of the device. That is, the field is established without any requirement for moisture accumulation on the support structure.

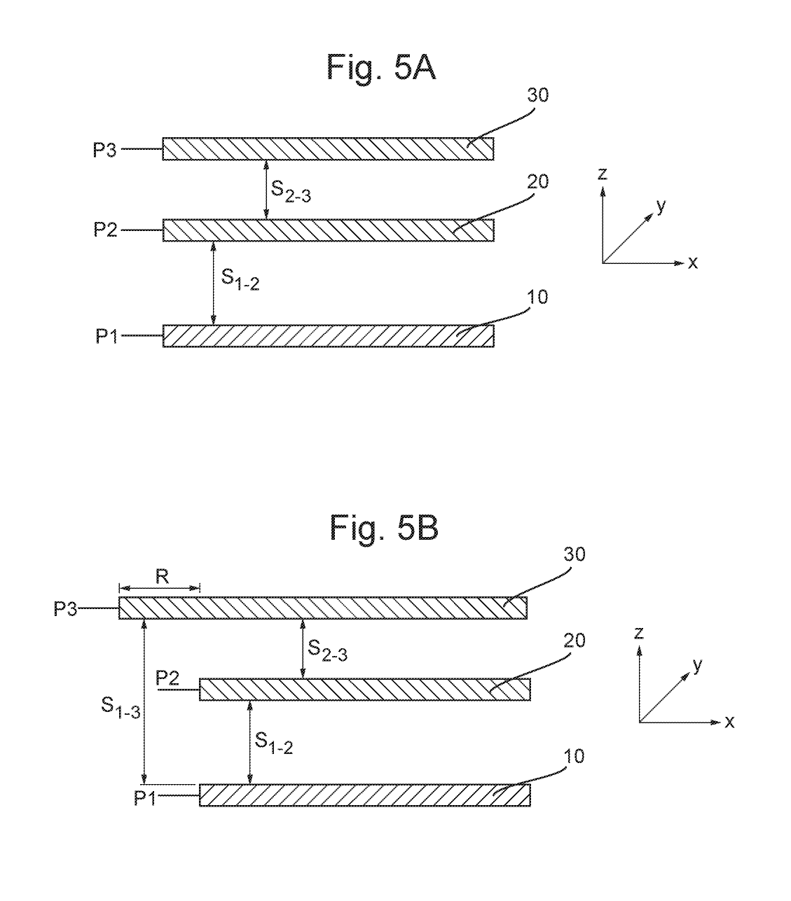

FIG. 4 shows an example of a system that is similar to that shown in FIGS. 3A and 3B (except that a third conductive element 30 is present), and illustrates the shape of the resulting electrical field. As shown in FIG. 4, the field established in a system comprising the third conductive element 30, including the fringing field F, can be similar or the same as the field arising in a system without a third conductive element (such as that shown in FIG. 3B) following a period of moisture accumulation.

By establishing a field at time zero (that is, initially when the MEMS transducer is activated before any moisture accumulation) that would otherwise have gradually arisen over time with increasing surface conductivity, the example shown in FIG. 4 can mitigate the effects of sensitivity drift with operational time. In FIG. 4, for illustrative purposes, the second and third conductive elements 20, 30 are shown as not extending across the entire surface of the support structure 25 however, depending on the specific requirements of the system, one or both of the second and third conductive elements 20, 30 may extend across the entire surface of the support structure 25.

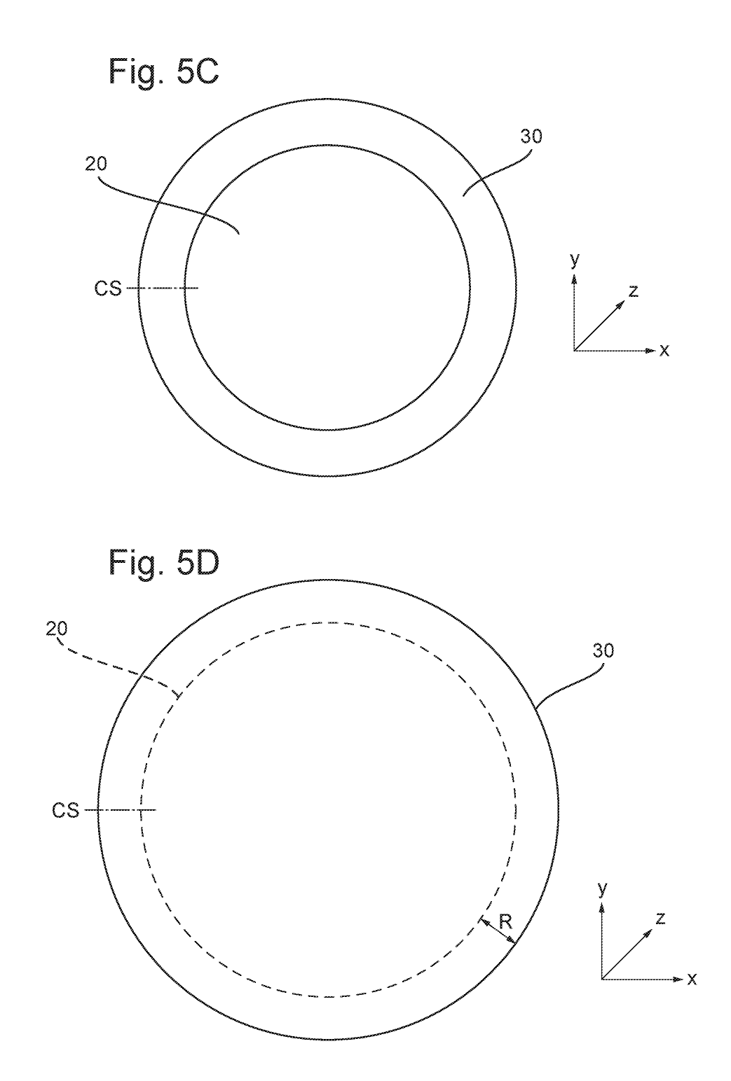

FIG. 5A and FIG. 5B each illustrate partial cross-sectional views to show the relative arrangement between a plurality of conductive elements which may form a MEMS capacitive transducer according to examples of the present embodiments. Other components of a MEMS transducer, such as support structures or a flexible membrane, are not shown for reasons of clarity and explanation. Mutually orthogonal axes x, y and z are marked on FIG. 5A, wherein the y axis is directed into the figure. These axes are used consistently to refer to the respective positions of components. Further, the direction of the shading fill lines in FIGS. 5A and 5B indicate the respective potentials of the conductive elements, that is, in FIGS. 5A and 5B two conductive elements having the same fill lines are at substantially the same potential.

In the configurations of FIGS. 5A and 5B, a first conductive element 10 provided in a first horizontal plane P1 forms a capacitor with a second conductive element 20 provided in a second horizontal plane P2. Thus the second conductive element is vertically spaced from the first conductive element 10 at a distance S₁₋₂ in a separation direction z.

In each of the examples shown in FIGS. 5A and 5B a third conductive element 30 is provided in a fringing field region of the capacitor defined by the first and second conductive elements 10, 20. The third conductive element 30 is spaced from the second conductive element 10 in the separation direction z. In FIG. 5A the third conductive element 30 is provided in a plane P3 above the plane P2 of the second conductive element 20, and the third conductive element 30 fully overlaps with the first conductive element 10 and the second conductive element 20. In FIG. 5A the third conductive element 30 is spaced from the second conducive element 20 at a distance S₂₋₃ in the separation direction z. In a typical example configuration, in an undisturbed (equilibrium) position, separation S₁₋₂ is approximately 2 to 3 μm, and separation S₂₋₃ is approximately 2 μm. These values assume that the third conductive element 30 is located on the top surface of the support element and the second conductive element 20 is located on the bottom surface of the same support element. One or both of the second and third conductive elements 20, 30 could be located within the support element or on a separate support element. Further the thickness of the support element and the spacing between the support element and the flexible membrane may also be varied. The values quoted above are for illustrative purposes only, and are not limiting.

A further example is illustrated in FIG. 5B in which the third conductive element 30 is again provided in a plane P3 above the plane P2 containing the second conductive element 20 but only partially overlaps with the second conductive electrode 20. Separation S₁₋₃ is also marked on FIG. 5B; in the illustrated example this value is equal to the sum of S₁₋₂, S₂₋₃ and the thickness of the second conductive element 20.

It will be appreciated that numerous different arrangements are envisaged within the context of the present embodiments, in addition to those specifically illustrated herein, by varying the relative horizontal and/or vertical positions of the three conductive elements 10, 20 and 30 and/or by varying the size and/or shape of the conductive elements 10, 20 and 30. Preferably, however, the third conducive element 30 is located above the second conductive element 20 and in close proximity (of the order of 1 to 10 μm) to the second conductive element 20, thereby allowing the third conductive element 30 to act as a field modifier for modifying the electric field arising in a fringing field region of the capacitor formed by the first and second conductive elements 10, 20. Thus, in addition to being located directly above the second conductive element 20, the third conductive element 30 may be located in a region above and adjacent to the second conductive element 20, whereby the third conductive element 30 partially overlaps the second conductive element 20 when viewed in a direction normal to the plane of the third conductive element 30. In particular, the edge of the third conductive element 30 may be offset from the edge of the first conductive element 10 and/or second conductive element 20 in direction x. In FIG. 5B, an edge of the third conductive element 30 is offset from an edge of the second conductive element 20 by distance R in the x direction.

In the examples, at least a part of the third conductive element 30 extends into the fringing field region. The third conductive element 30 is configured to be at substantially the same voltage as the second conductive element 20. In particular, this may be beneficially achieved by a direct physical and electrical connection between the second conductive element 20 and the third conductive element 30, which may result in the second conductive element 20 being at the same potential as the third conductive element 30. For example, one or more conductive tracks or columns may be provided which extend between the plane of the second conductive element 20 and the plane of the third conductive element 30. This is a simple and readily implemented way of configuring the third electrode 30 to be at the same potential as the second conductive electrode 20, and is discussed in greater detail below.

It will be appreciated that the fringing field region will extend all the way around the capacitor defined by the first and second conducive elements 10, 20. Thus, according to one or more examples it may be desirable for the third conductive element 30 to be provided so as to define a region of conductive material, within the fringing field region, which extends in a region outside the boundary of the capacitor when viewed from a position above the plane of the third conductive element 30. Thus, the third conductive element 30 may advantageously define a closed loop of conductive material. The shape of the loop may depend on the shape of the first and second electrodes 10, 20 which may be e.g. square/rectangular or circular. In particular, the shape of the third conductive element 30 may substantially correspond to the shape of the first and second electrodes 10, 20. In the case of a capacitor formed of circular planar electrodes, the third conductive element 30 may for example take the form of an annulus, or a solid disk. Alternatively, the third conductive element 30 may comprise a plurality of discrete sub-elements of conductive material arranged at intervals around the fringing field region. Preferably, the sub-elements will be configured to be at substantially the same voltage.

FIG. 5C and FIG. 5D illustrate second and third conductive elements 20, 30 of MEMS transducers. The first conductive element is not shown in either of FIGS. 5C and 5D; the first conductive element is obscured by the second conductive element 20 in both figures. FIG. 5C illustrates a plan view of conductive elements in accordance with the partial cross section in FIG. 5A, and FIG. 5D illustrates a plan view of conductive elements in accordance with the partial cross section in FIG. 5B. The position of the partial cross sections of FIGS. 5A and 5B is indicated in FIGS. 5C and 5D by the line CS. The relative orientations of the x, y and z axes are also shown on FIGS. 5C and 5D. In both figures, the z axis is directed into the figure.

In FIGS. 5C and 5D the first and second conductive elements are both generally circular in shape (as discussed above, other element shapes may also be used) and define a parallel plate capacitor. In these figures, the first and second conductive elements are the same size and aligned to fully overlap with one another, although this is not always the case. The parallel plate capacitor is defined in the region where the first and second conductive elements overlap; in FIGS. 5C and 5D this corresponds to the entire surface areas of the first and second conductive elements, although this is not the case where the elements do not fully overlap with one another.

A fringing field region laterally surrounds the region of the capacitor. The third conducive element 30 provides complete coverage of the boundary region of the capacitor and is provided in a plane above the plane of the second conductive element 20.

In FIG. 5C, the third conductive element 30 is provided so as to fully overlap the second conductive element 20, when viewed in a direction normal to the plane of the second conductive element 20 (as shown). That is, when viewed in a direction normal to the plane of the second conductive element 20 such that the plane of the third conductive element 30 is in front of the plane of the second conductive element, all of the third conductive element 30 is directly in front of a part of the second conductive element. However, as the third conductive element 30 in FIG. 5C is annular, as discussed above, portions of the second conductive element 20 are not obscured by the third conductive element 30 when viewed in the direction. Specifically, the central portion of the second conductive element 20 is not obscured in FIG. 5C.

In FIG. 5D, the third conductive element 30 is provided so as to partially overlap with the second conductive element 20 and also extend into a region not overlapping the second conductive element 20, when viewed in a direction normal to the plane of the second conductive element 20 (as shown). The third conductive element 30 in FIG. 5D extends beyond the edge of the second conductive element 20 by distance R. In contrast to the third conductive element of FIG. 5C, the third conductive element of FIG. 5D is disc shaped, rather than annular. The boundary of the second conductive element 20 (which is obscured by the third conductive element 30) is indicated by a dashed line in FIG. 5D.

FIG. 5E illustrates a plan view of first, second and third conductive elements of further example embodiment of a MEMS transducer. The general form of this example is the same as that of FIG. 5C (in particular, the first conductive element is not shown), except that in FIG. 5E the third conductive element 30 comprises a plurality of discrete sub-elements 30a, 30b, 30c and 30d of conductive material. These may be beneficially arranged at regular intervals around the fringing field region as shown, or may be arranged in an irregular fashion. Preferably, the discrete sub-elements 30a-d will be configured to be at substantially the same voltage as one another. Each of the discrete sub-elements 30a-d which form the third conductive element 30 is configured to be at a potential substantially the same as that of the second conductive element 20. The use of 4 discrete sub-elements is an example only; n sub-elements may be used as required where n is an integer greater than 2.

According to examples described herein, the extent of the fringing field region, and thus the preferred proximity of the third conductive element 30 to the second conductive element 20, depends on a number of factors including the material used for the conductive elements, the separation distance between the first and second electrodes 10, 20 and the potential difference between them. However, it is envisaged that the distance between the second and third conductive elements 10, 20 is between 1 μm and 50 μm, preferably between 1 μm and 10 μm and more preferably between 2 μm and 4 μm.

Depending on the precise manner of fabrication, it may be convenient for the third conductive element 30 to be deposited during the deposition of conductive material that forms either the membrane electrode or the backplate electrode. Alternatively, where the MEMS transducer is fabricated at least in part through successive applications of layers of material, the material forming the third conductive element 30 may be deposited before or after the material forming the other conductive elements. The conductive material may be metal, such as aluminium, or a metal-alloy such as aluminium-silicon alloy or titanium nitride. Alternatively the conductive material may be a conductive dielectric material, such as include titanium nitride, polysilicon, silicon carbide, amorphous silicon, tantalum nitride.

The third conductive element 30 is configured to operate at the substantially the same potential as the second conductive element 20. Particularly (although not exclusively) in configurations wherein the second conductive element 20 and third conductive element 30 are both supported by the same rigid support structure, the second conductive element 20 and third conductive element 30 may be physically and electrically connected to one another. Alternatively, the third conductive element 30 may be operated at the same potential as the second conductive element 20 without a direct electrical connection between the two. Also, where the second and third conductive elements 20, 30 are both supported by the same rigid support structure, the second conductive element 20 and third conductive element 30 may be separated by the material forming the support structure, which is typically an insulating material as discussed above.

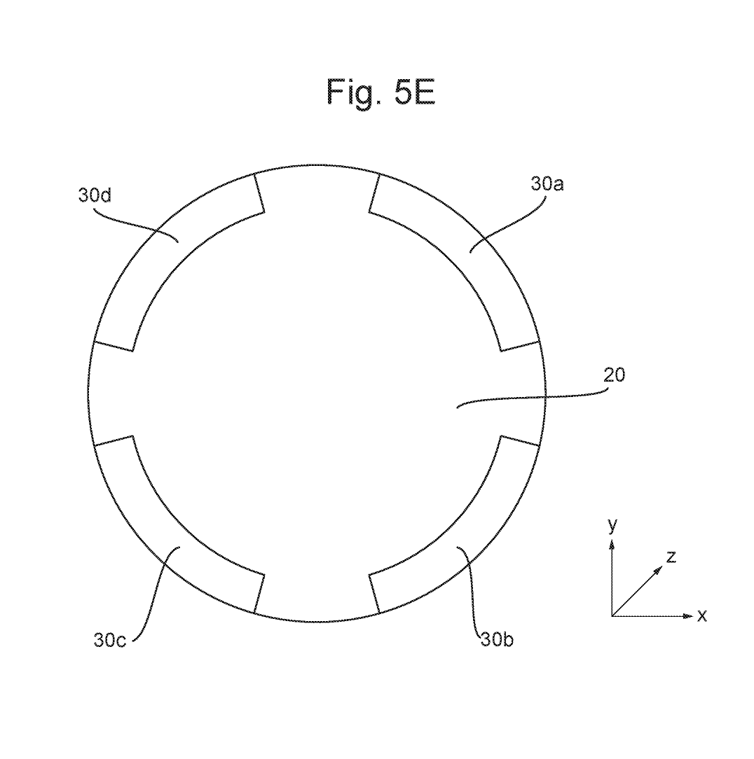

According to one or more examples, and with reference to FIG. 6, a conductive path 40 directly connects the third conductive element 30 with the second conductive element 20. This may be achieved by means of e.g. one or more vias and/or a conductive or metal tracks which extend between the planes of the second and third conductive elements 20, 30. In the example illustrated in FIG. 6 a first conductive track 40a extends from an edge of the second conductive element 20 to a metal via 50 located in the support structure. Furthermore, a second conductive track 40b extends from the edge of the third conductive element 30 to the metal via 50. In this way, a direct conductive path is provided between the third conductive element 30 and the second conductive element 20. This arrangement provides a simple way to configure the third conductive element 30 so as to be at a potential that is substantially the same as the potential of the second conductive element 20. In particular, where the impedance of a conductive path 40 between the second conductive element 20 and the third conductive element 30 is low, the second conductive element 20 and the third conductive element 30 may be at the same potential. Furthermore, according to embodiments of the present invention in which the first and second conductive elements 10, 20 are supported by one or more layers of dieletric material, for example one of the first and second conductive elements 10, 20 may be supported by a membrane formed of a dieletric material such as silicon nitride, and the other of first and second conductive elements may be supported by a dieletric material which forms a rigid support structure or backplate of the transducer, the fabrication of the transducer will involve the deposition of several conductive layers to form the first and second conductive elements 10, 20. Thus, the additional deposition of conductive metal to form the third conductive element 30, as well as a conductive path 40 between the second and third conductive elements 20, 30, requires only a minor modification to the established fabrication process.

Alternatively, embodiments are envisaged in which a circuit is provided which allows the potential of the third conductive element 30 to be set to be at a potential that differs from the first conductive element 10, and is set to be substantially the same as the second conductive element 20 potential. According to one or more example, a bias voltage is applied to the third conductive element 30 which is substantially equal to a bias voltage applied to the second electrode 20. According to other examples, the second conductive element 20 and the third conductive element 30 are configured to be coupled to ground. Where high impedance couplings are used to couple the second conductive element 20 and the third conductive element 30 to ground, this may allow small variations (up to 1 V) in the potential of the second conductive element 20 and the third conductive element 30. Therefore, despite being coupled to ground, the second conductive element 20 and the third conductive element 30 may not always be at exactly the same potential (of 0 V). However, the second conductive element 20 and the third conductive element 30 will remain at substantially the same potential. Equally, if the second conductive element 20 and the third conductive element 30 are coupled to a bias voltage through high impedance couplings, this may allow small variations (up to 1 V) in the potential of the second conductive element 20 and the third conductive element 30, but the second conductive element 20 and the third conductive element 30 will remain at substantially the same potential.

In order for MEMS transducer to function as a capacitive sensor, a potential difference is established between the first and second conductive elements 10, 20. As such, the third conductive element 30, which is set at substantially the same potential as the second conductive element 20 and may be at exactly the same potential as the second conductive element 20, is at a different potential to the first conductive element 10.

As discussed above, a transducer according to examples of the present embodiments will preferably be provided with a rigid support structure, such as a backplate. Thus, the backplate may support either the first conductive element 10 or the second and third conductive elements 20, 30. Such backplate structures are typically provided with acoustic holes to allow free movement of air molecules through the backplate. Thus, it will be appreciated that any of the examples described herein may be arranged such that the first conductive element 10 is provided on a flexible membrane of the transducer whilst the second conductive element 20 is supported by (either formed on or embedded within) a rigid support structure such as a backplate. Alternatively, the first conductive element 10 may be supported by the backplate whilst the second conductive element 20 is formed on the flexible membrane. In either case, the third conductive element 30 is spaced from the second conductive element 20 in the separation direction whilst being held at or close to the same potential as the second conductive element 20. Thus, the third conductive element 30 may be conveniently supported by either the membrane or the backplate structure.

Where the backplate structure comprises a plurality of holes—e.g. acoustic holes, the backplate electrode—which may be the first or second conductive element 10, 20 within the context of the present invention—will also be patterned to comprise a plurality of holes which correspond to the acoustic holes formed in the backplate. The membrane electrode may also be patterned to incorporate a plurality of holes such that at least a part of the area of at least one opening in the membrane electrode corresponds to the area of at least one hole in the backplate electrode. It will be appreciated that the size of the backplate holes may be the same as the size of some of the openings in the membrane electrode, although this need not necessarily be the case.

The holes or openings in the membrane electrode or the backplate electrode may be of any shape, for example circular or polygonal (e.g. square) in shape. In particular, the openings in the membrane electrode may be hexagonal in shape.

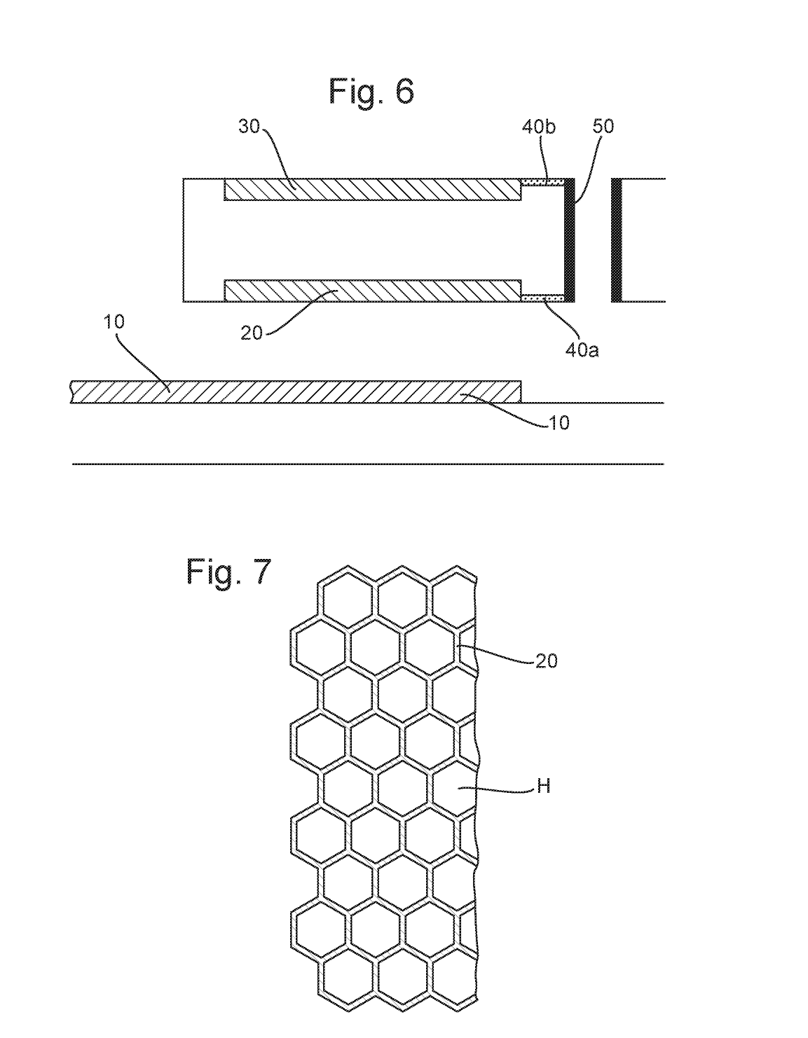

FIG. 7 illustrates a part of a second conductive element 20 which comprises a plurality of hexagonal holes H. The second conductive element 20 may form a backplate electrode or a membrane electrode of a transducer. A first conductive element (not shown) may, for example, be a patterned electrode having a plurality of openings that are arranged so as to be mutually overlapping with the holes of the second conductive element 20. A third conductive element (also not shown) may be formed so as to provide a planar surface, without holes, overlying the plane of the second conductive element 20. However, preferably, the third conductive element may be provided so as to substantially replicate the shape of the second conductive element 20, such that the third conductive element comprises a plurality of openings that are arranged to mutually overlap the holes in the second conductive element 20 (and preferably also holes in the first conductive element). In this way, the third conductive element may be arranged to substantially overlie the second conductive element 20, when viewed in a direction normal to the plane of the second conductive element 20.

According to examples described herein the third conductive element 30 advantageously modifies the shape of a fringing electric field arising between the first and second conductive elements 10, 20 (said first and second conducting elements 10, 20 forming a capacitor). Thus, the third conductive element 30 can be considered to be a field modifier. Surprisingly, examples described herein which provide a MEMS transducer comprising a third conductive element 30 or field modifier have been shown to demonstrate a significant improvement in the time-dependent sensitivity drift of the transducer. Thus, MEMS transducers according to the present example embodiments benefit from a more stable performance (that is, a more stable electric field over time) and, potentially, an improved utilisation in applications which require, or would benefit from, enhanced levels of performance stability.

The flexible membrane may comprise a crystalline or polycrystalline material, such as one or more layers of silicon-nitride Si₃N₄.

MEMS transducers according to the present examples will typically be associated with circuitry for processing an electrical signal generated as a result of detected movement of the flexible membrane, either by a capacitive sensing technique or by an optical sensing technique. Thus, in order to process an electrical output signal from the microphone, the transducer die/device may have circuit regions that are integrally fabricated using standard CMOS processes on the transducer substrate.

The circuit regions may be fabricated in the CMOS silicon substrate using standard processing techniques such as ion implantation, photomasking, metal deposition and etching. The circuit regions may comprise any circuit operable to interface with a MEMS transducer and process associated signals. For example, one circuit region may be a pre-amplifier connected so as to amplify an output signal from the transducer. In addition another circuit region may be a charge-pump that is used to generate a bias, for example 12 volts, across the two electrodes. This has the effect that changes in the electrode separation (i.e. the capacitive plates of the microphone) change the MEMS microphone capacitance; assuming constant charge, the voltage across the electrodes is correspondingly changed. A pre-amplifier, preferably having high impedance, is used to detect such a change in voltage.

The circuit regions may optionally comprise an analogue-to-digital converter (ADC) to convert the output signal of the microphone or an output signal of the pre-amplifier into a corresponding digital signal, and optionally a digital signal processor to process or part-process such a digital signal. Furthermore, the circuit regions may also comprise a digital-to-analogue converter (DAC) and/or a transmitter/receiver suitable for wireless communication. However, it will be appreciated by one skilled in the art that many other circuit arrangements operable to interface with a MEMS transducer signal and/or associated signals, may be envisaged.

It will also be appreciated that, alternatively, the microphone device may be a hybrid device (for example whereby the electronic circuitry is totally located on a separate integrated circuit, or whereby the electronic circuitry is partly located on the same device as the microphone and partly located on a separate integrated circuit) or a monolithic device (for example whereby the electronic circuitry is fully integrated within the same integrated circuit as the microphone).

Examples described herein may be usefully implemented in a range of different material systems, however the examples described herein are particularly advantageous for MEMS transducers having membrane layers comprising silicon nitride.

One or more MEMS transducers according to the examples described here may be located within a package. This package may have one or more sound ports. A MEMS transducer according to the examples described here may be located within a package together with a separate integrated circuit comprising readout circuitry which may comprise analogue and/or digital circuitry such as a low-noise amplifier, voltage reference and charge pump for providing higher-voltage bias, analogue-to-digital conversion or output digital interface or more complex analogue or digital signal processing.

A MEMS transducer according to the examples described here may be located within a package having a sound port.

It is noted that the example embodiments described above may be used in a range of devices, including, but not limited to: analogue microphones, digital microphones, pressure sensor or ultrasonic transducers. The example embodiments may also be used in a number of applications, including, but not limited to, consumer applications, medical applications, industrial applications and automotive applications. For example, typical consumer applications include portable audio players, laptops, mobile phones, PDAs and personal computers. Example embodiments may also be used in voice activated or voice controlled devices. Typical medical applications include hearing aids. Typical industrial applications include active noise cancellation. Typical automotive applications include hands-free sets, acoustic crash sensors and active noise cancellation.

Features of any given aspect or example embodiment may be combined with the features of any other aspect or example embodiment and the various features described herein may be implemented in any combination in a given embodiment.

Associated methods of fabricating a MEMS transducer are provided for each of the example embodiments.

It should be understood that the various relative terms above, below, upper, lower, top, bottom, underside, overlying, underlying, beneath, etc. that are used in the present description should not be in any way construed as limiting to any particular orientation of the transducer during any fabrication step and/or it orientation in any package, or indeed the orientation of the package in any apparatus. Thus the relative terms shall be construed accordingly.

In the examples described above it is noted that references to a transducer may comprise various forms of transducer element. For example, a transducer may be typically mounted on a die and may comprise a single membrane and back-plate combination. In another example a transducer die comprises a plurality of individual transducers, for example multiple membrane/back-plate combinations. The individual transducers of a transducer element may be similar, or configured differently such that they respond to acoustic signals differently, e.g. the elements may have different sensitivities. A transducer element may also comprise different individual transducers positioned to receive acoustic signals from different acoustic channels.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference signs in the claims shall not be construed so as to limit their scope. For the avoidance of doubt, the scope of the invention is defined by the claims.

1. A MEMS transducer comprising first and second conductive elements, the second conductive element being provided in a plane which overlies a plane of the first conductive element, wherein a mutually overlapping region of the first and second conductive elements defines a capacitor of the transducer,
the transducer further comprising a third conductive element, wherein the third conductive element is provided in a plane that overlies the plane of the second conductive element and wherein the third conductive element is configured to be at a potential substantially the same as the potential of the second conductive element,
wherein the second conductive element lies at least partially between the first conductive element and the third conductive element.

2. A MEMS transducer as claimed in claim 1, wherein the third conductive element is provided in a fringing field region of the capacitor.

3. A MEMS transducer as claimed in claim 1, wherein the third conductive element is electrically connected to the second conductive element.

4. (canceled)

5. A MEMS transducer as claimed in claim 34, wherein the conductive path comprises a conductive track, and/or wherein the conductive path comprises a conductive via.

6. (canceled)

7. A MEMS transducer as claimed in claim 1, wherein the third conductive element fully overlies the second conductive element when viewed in a direction normal to the third conductive element.

8. (canceled)

9. A MEMS transducer as claimed in claim 1, wherein a region between the third conductive element and the second conductive element is substantially occupied by an insulating material.

10. A MEMS transducer as claimed in claim 1, wherein the first conductive element is supported by a flexible membrane of the MEMS transducer and the second electrode is supported by a fixed support structure of the MEMS transducer, optionally wherein the third conductive element is supported by the fixed support structure.

11. (canceled)

12. A MEMS transducer as claimed in claim 10, wherein the flexible membrane comprises a crystalline or polycrystalline material, and/or wherein the flexible membrane and/or the fixed support structure are formed of a dielectric material, optionally wherein the dielectric material comprises silicon nitride.

13-14. (canceled)

15. A MEMS transducer as claimed in claim 1, wherein the second conductive element comprises a hexagonal lattice structure, optionally wherein the third conductive element comprises a hexagonal lattice structure which substantially overlies the hexagonal lattice structure of the second conductive element when viewed in a direction normal to the plane of the second conductive element.

16. (canceled)

17. A MEMS transducer as claimed in claim 1, wherein one or more of the first, second and third conductive elements comprise a metal or a metal alloy.

18. A MEMS transducer as claimed in claim 1, wherein a bias voltage is applied to the third conductive element and wherein the bias voltage is substantially equal to a bias voltage applied to the second conductive element, or wherein the second conductive element and the third conductive element are coupled to ground potential.

19. (canceled)

20. A MEMS transducer as claimed in claim 1, wherein the third conductive element is a field modifier provided in a fringing field region of the capacitor, the field modifier located to provide a stable electric field between the first conductive element and the field modifier.

21. A MEMS transducer comprising:
a flexible membrane;
a rigid backplate;
a membrane electrode formed on an upper surface of the membrane;
a backplate electrode, formed on or within the backplate;
a third conductive element provided at a potential the same as the potential of the backplate electrode;
wherein the backplate electrode lies at least partially between the membrane electrode and the third conductive element.

22. A MEMS transducer as claimed in claim 21, wherein the membrane is formed of a dielectric material, and/or wherein the backplate is formed of a dielectric material.

23. (canceled)

24. A MEMS capacitive transducer comprising first and second parallel plates, the transducer further comprising a third plate, wherein the third plate is provided in a plane that overlies the plane of the second plate so that the second plate lies at least partially between the first plate and the second plate, and wherein the third plate is configured to be at a potential the same as the potential of the second plate.

25. A MEMS transducer as claimed in claim 1, wherein said transducer comprises a capacitive sensor, and/or wherein said transducer comprises a microphone, and/or wherein said transducer comprises readout circuitry, wherein the readout circuitry may comprise analogue and/or digital circuitry.

26-28. (canceled)

29. A MEMS transducer as claimed in claim 1, wherein the transducer is located within a package having a sound port, optionally wherein the transducer is arranged within the package such that the membrane layer directly faces the acoustic port.

30. (canceled)

31. An electronic device comprising a MEMS transducer as claimed in claim 1.

32. An electronic device as claimed in claim 31 wherein said device is at least one of: a portable device; a battery powered device; an audio device; a computing device; a communications device; a personal media player; a mobile telephone; a games device; and a voice controlled device.

33. An integrated circuit comprising a MEMS transducer as claimed in claim 1 and readout circuitry.

34. A MEMS transducer as claimed in claim 3, wherein a conductive path directly connects the third conductive element to the second conductive element.
